(19) United States
(12) Patent Application Publication
(10) Pub. No.: US 2025/0230355 A1
(43) Pub. Date: Jul. 17, 2025

(54) COMPOSITION FOR REMOVING EDGE BEAD FROM METAL CONTAINING RESISTS, DEVELOPER COMPOSITION OF METAL CONTAINING RESISTS, AND METHOD OF FORMING PATTERNS USING THE COMPOSITION

(71) Applicant: SAMSUNG SDI CO., LTD., Yongin-si (KR)

(72) Inventors: Taeho KIM, Suwon-si (KR); Gyeonghun PARK, Suwon-si (KR); Hyungrang MOON, Suwon-si (KR); Si-Kyun PARK, Suwon-si (KR); Jin-Hee BAE, Suwon-si (KR); Seung HAN, Suwon-si (KR); Taeksoo KWAK, Suwon-si (KR); Jongpil HO, Suwon-si (KR); Myoungsoo SONG, Suwon-si (KR); Miyeon HAN, Suwon-si (KR)

(21) Appl. No.: 18/955,415

(22) Filed: Nov. 21, 2024

(30) Foreign Application Priority Data
Jan. 17, 2024 (KR) 10-2024-0007650

(51) Int. Cl. C09K 13/00; G03F 7/004; H01L 21/027

(52) U.S. Cl. CPC C09K 13/00; G03F 7/0042; H01L 21/0274

(57) ABSTRACT

A composition for removing edge beads from metal-containing resists and/or a developer composition of metal-containing resists, and a method of forming patterns using the same are provided. The composition includes a polycyclic aliphatic hydrocarbon compound substituted with at least one carboxyl group; and an organic solvent.

### CROSS-REFERENCE TO RELATED APPLICATION

The present application claims priority to and the benefit of Korean Patent Application No. 10-2024-0007650, filed on Jan. 17, 2024, in the Korean Intellectual Property Office, the entire disclosure of which is incorporated herein by reference.

### BACKGROUND

### 1. Field

This disclosure relates to compositions for removing edge beads from metal containing resist, developer compositions of metal-containing resists, and a method of forming patterns using the same.

### 2. Description of the Related Art

In recent years, the semiconductor industry has been accompanied by (e.g., has seen) a substantially continuous reduction of critical dimensions, and this dimensional reduction requires new types (kinds) of high-performance photoresist materials and a patterning method that satisfy a demand or desire for processing and patterning with increasingly smaller features.

In addition, with the recent rapid development of the semiconductor industry, a semiconductor device is desired or required to have a fast operation speed and large storage capacity, and in line with this requirement, process technology for improving integration, reliability, and a response speed of the semiconductor device is being developed or pursued. For example, it is important or desirable to accurately control/implant impurities in working regions of a silicon substrate and to interconnect these regions to form a device and/or an ultra-high-density integrated circuit, which may be achieved by a photolithographic process. For example, it is important or desirable to integrate the photolithographic process including coating a photoresist on the substrate, selectively exposing it to ultraviolet (UV) (including extreme ultraviolet (EUV)), electron beams, X rays, and/or the like, and then, developing it.

For example, in the process of forming the photoresist layer, while rotating the silicon substrate, the resist is mainly coated on (e.g., a top surface of) the substrate, but the resist may also be coated on an edge and rear surface of the substrate, which may generate particles and/or cause pattern defects in the subsequent semiconductor processes such as etching and/or ion implantation processes. Accordingly, a process of stripping and removing the photoresist coated on the edge and rear surface of the silicon substrate by using a thinner composition, that is, an edge bead removal (EBR) process is performed. The EBR process requires or desires a composition that exhibits excellent or suitable solubility for the photoresist and effectively removes beads and the photoresist remaining in the substrate and generates no resist residue.

There is also a need or desire to develop a photoresist that can ensure excellent or suitable etch resistance and resolution in the photolithography process, while improving sensitivity and critical dimension (CD) uniformity, and can improve line edge roughness (LER) characteristics, and a developer composition that can implement these needed or desired features.

### SUMMARY

Aspects according to one or more embodiments are directed toward a composition for removing edge beads from metal-containing resists and/or a developer composition of metal-containing resists.

Aspects according to one or more embodiments are directed toward a method of forming patterns using the composition.

Additional aspects will be set forth in part in the description which follows and, in part, will be apparent from the description, or may be learned by practice of the presented embodiments of the disclosure.

According to one or more embodiments, a composition (e.g., a solvent-based composition) includes a polycyclic aliphatic hydrocarbon compound substituted with at least one carboxyl group; and an organic solvent. Here, the solvent-based composition maybe a composition for removing edge beads from metal-containing resists or a developer composition of metal-containing resists.

According to one or more embodiments, a method of forming patterns includes coating a metal-containing photoresist composition on a substrate; coating an edge beads removing composition for removing edge beads from metal-containing resists along an edge of the substrate to remove an edge bead; drying and heating to form a metal-containing photoresist layer on the substrate; exposing the metal-containing photoresist layer; and developing the metal-containing photoresist layer using a developer composition,
wherein at least one of the edge beads removing composition or the developer composition includes the aforementioned composition.

The composition for removing edge beads from the metal-containing resists according to one or more embodiments reduces the metal-based contamination inherent in the metal-containing resists and removes the resist coated on the edge and the rear surface of the substrate, thereby satisfying requirements of processing and patterning of smaller features.

The developer composition of metal-containing resists according to one or more embodiments may implement excellent or suitable contrast characteristics, excellent or suitable sensitivity, and reduced line edge roughness (LER) by minimizing or reducing defects present in the metal-containing photoresist layer after the exposure process and facilitating development.

### BRIEF DESCRIPTION OF THE DRAWINGS

The above and other aspects, features, and enhancements of certain embodiments of the disclosure will be more apparent from the following description taken in conjunction with the accompanying drawings, in which:

FIG. 1 is a schematic view of a photoresist coating apparatus.

FIG. 2 is a cross-sectional view schematically showing the process sequence of a method of forming patterns according to one or more embodiments of the present disclosure.

### DETAILED DESCRIPTION

Hereinafter, embodiments of present disclosure are described in more detail with reference to the accompanying drawings. In the following description of the present disclosure, the known functions or constructions will not be described in order to clarify the present disclosure.

In order to clearly illustrate the present disclosure, the description and relationships that should be understood by those of ordinary skill in the art are not provided, and throughout the disclosure, the same or similar configuration elements are designated by the same reference numerals. Also, because the size and thickness of each configuration shown in the drawings are arbitrarily shown for better understanding and ease of description, the present disclosure is not necessarily limited thereto.

In the drawings, the thickness of layers, films, panels, regions, and/or the like, may be exaggerated for clarity. In the drawings, the thickness of a part of layers, regions, and/or the like, may be exaggerated for clarity. It will be understood that if (e.g., when) an element such as a layer, film, region, or substrate is referred to as being “on” another element, it can be directly on the other element or intervening elements may also be present.

In the present disclosure, the term “substituted” refers to replacement of a hydrogen atom by deuterium, a halogen, a hydroxyl group, a thiol group, a cyano group, a carbonyl group, a carboxyl group, an amino group, an amide group, an ester group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a C1 to C20 sulfide group. As used herein, the term “unsubstituted” refers to that a hydrogen atom remains as a hydrogen atom without being replaced by another substituent.

In the present disclosure, the term “alkyl group” refers to a linear or branched aliphatic hydrocarbon group, unless otherwise defined. The alkyl group may be a “saturated alkyl group” that does not contain any double or triple bonds.

The alkyl group may be a C1 to C20 alkyl group. For example, the alkyl group may be a C1 to C10 alkyl group or a C1 to C6 alkyl group. For example, a “C1 to C5 alkyl group” refers to that the alkyl chain contains 1 to 5 carbon atoms, and may be selected from among methyl, ethyl, propyl, iso-propyl, n-butyl, iso-butyl, sec-butyl, and t-butyl.

Non-limiting examples of the alkyl group include a methyl group, an ethyl group, a propyl group, an isopropyl group, a butyl group, an isobutyl group, a tert-butyl group, a pentyl group, a hexyl group, and/or the like.

In the chemical formulas described herein, “t-Bu” refers to a tert-butyl group.

In the present disclosure, if (e.g., when) a definition is not otherwise provided, the term “cycloalkyl group” refers to a monovalent cyclic aliphatic hydrocarbon group.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but the present disclosure is not limited thereto.

In the present disclosure, if (e.g., when) a definition is not otherwise provided, the term “heterocycloalkyl group” refers to a cycloalkyl group including at least one hetero atom selected from among N, O, S, P, and Si.

In the present disclosure, if (e.g., when) a definition is not otherwise provided, the term “alkenyl group” refers to a linear or branched aliphatic hydrocarbon group, and may refer to an aliphatic unsaturated alkenyl group containing one or more double bonds.

In the present disclosure, if (e.g., when) a definition is not otherwise provided, the term “alkynyl group” refers to a linear or branched aliphatic hydrocarbon group, and may refer to an unsaturated alkynyl group containing one or more triple bonds.

In the present disclosure, the term “aryl group” refers to a substituent in which all elements of a cyclic substituent have p-orbitals, and these p-orbitals form a conjugate and may include monocyclic, polycyclic or fused ring (i.e., rings that share adjacent pairs of carbon atoms) functional groups.

For example, the term “a heteroaryl group” may refer to an aryl group including at least one heteroatom selected from among N, O, S, P, and Si. Two or more heteroaryl groups may be linked by a sigma bond directly, or if (e.g., when) the heteroaryl group includes two or more rings, the two or more rings may be fused. If (e.g., when) the heteroaryl group is a fused ring, each ring may include one to three heteroatoms.

For example, the substituted or unsubstituted C6 to C30 aryl group may be a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted benzophenanthrenyl group, a substituted or unsubstituted triphenylene group, a substituted or unsubstituted perylenyl group, a substituted or unsubstituted fluorenyl group, a substituted or unsubstituted indenyl group, and/or a (e.g., any suitable) combination thereof, but the present disclosure is not limited thereto.

For example, the substituted or unsubstituted C2 to C30 heterocyclic group may be a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzothiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted carbazolyl group, a substituted or unsubstituted dibenzofuranyl group, or a substituted or unsubstituted dibenzothiophenyl group, a substituted or unsubstituted benzonaphthofuranyl group, a substituted or unsubstituted benzonaphthothiophenyl group, a substituted or unsubstituted benzofuranofluorenyl group, a substituted or unsubstituted benzothiophenefluorenyl group, and/or a (e.g., any suitable) combination thereof, but the present disclosure is not limited thereto.

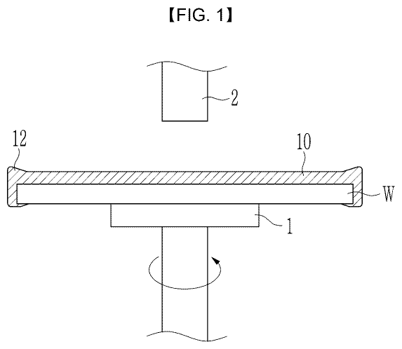

FIG. 1 is a schematic view showing the photoresist coating apparatus.

Referring to FIG. 1, a substrate support portion 1 on which a substrate W is placed is equipped therewith (e.g., within the photoresist coating apparatus), and the substrate support portion 1 includes a spin chuck or a spin coater.

The substrate support portion 1 rotates in a first direction at a set or predetermined rotation speed to provide a centrifugal force to the substrate W. A spray nozzle 2 may be positioned over (or on) the substrate support portion 1 but located off the upper portion of the substrate W in the atmospheric region (e.g., the spray nozzle 2 may be spaced and/or apart (e.g., spaced apart) from the upper surface of the substrate W) so that the spray nozzle may be moved toward the upper portion of the substrate W and spray a photoresist solution 10 in the spraying (e.g., act or task) step. Accordingly, the photoresist solution 10 is coated on the surface of the substrate W by the centrifugal force. Herein, while the photoresist solution 10 supplied to the center of the substrate W is coated by spreading to the edge of the substrate W by the centrifugal force, a portion of the photoresist solution 10 moves to the side surfaces of the substrate W and the lower surface of the edge of the substrate.

For example, in the coating process, the photoresist solution 10 is coated (e.g., mainly) by a spin coating method, in which a set or predetermined amount of the photoresist solution 10 with (e.g., a suitable) viscosity is supplied to the center portion of the substrate W and gradually spreads toward the edge of the substrate W by the centrifugal force.

Accordingly, the photoresist is evenly formed through a rotational movement (e.g., speed) of the substrate support portion.

This rotation also evaporates a solvent from the solution (e.g., the photoresist solution 10) and thereby the viscosity thereof is gradually increased, resulting in a portion (e.g., a relatively large amount) of the photoresist accumulated on the edge of the substrate by the action of surface tension and even onto the lower surface of the edge of the substrate, which is referred to as edge beads 12.

Hereinafter, a composition for removing edge beads from metal-containing resists (e.g., metal-containing photoresists) and/or a developer composition of metal-containing resists according to one or more embodiments is described.

The composition for removing edge beads from metal-containing resists or developer composition of metal-containing resists according to one or more embodiments includes a polycyclic aliphatic hydrocarbon compound substituted with at least one carboxyl group; and an organic solvent.

In one or more embodiments, the polycyclic aliphatic hydrocarbon compound substituted with at least one carboxyl group may be represented by Chemical Formula 1.

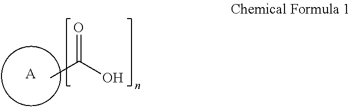

In Chemical Formula 1,
A is a substituted or unsubstituted C5 to C50 polycyclic aliphatic hydrocarbon group in which at least two rings are fused, and
n is an integer of 1 or greater.

By including the polycyclic aliphatic hydrocarbon compound substituted with at least one carboxyl group, the sensitivity can be adjusted so that contrast is expressed for a photoresist layer in a low exposure energy state, thereby further increasing a difference in solubility between the exposed region and the non-exposed region.

In the present disclosure, the term “polycyclic aliphatic hydrocarbon compound” refers to a fused ring structure in which two or more rings share one or more pairs of carbon atoms. For example, it may refer to a bridged polycyclic aliphatic hydrocarbon compound having 5 to 50 carbon atoms.

The polycyclic aliphatic hydrocarbon compound may include, for example adamantane, norbornane, isobornane, tricyclodecane, tetracyclododecane, bicyclo[2,2,1]heptane, and/or the like, but the present disclosure is not limited thereto.

In one or more embodiments, A may be a substituted or unsubstituted adamantyl group, a substituted or unsubstituted norbornyl group, a substituted or unsubstituted isobornyl group, a substituted or unsubstituted tricyclodecanyl group, a substituted or unsubstituted tetracyclododecanyl group, a substituted or unsubstituted bicyclo[2.2.1]heptyl group, and/or a (e.g., any suitable) combination thereof.

As a non-limiting specific example, the polycyclic aliphatic hydrocarbon compound substituted with a carboxyl group may be any one selected from among the compounds listed in Group 1.

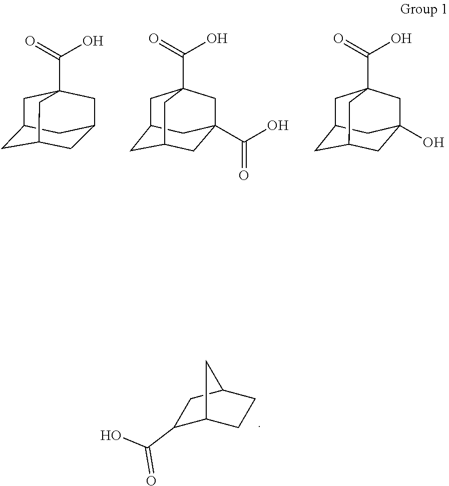

The polycyclic aliphatic hydrocarbon compound substituted with at least one carboxyl group may be included in an amount of about 0.1 wt % to about 10 wt % based on a total weight of the composition.

For example, the polycyclic aliphatic hydrocarbon compound substituted with at least one carboxyl group may be included in an amount of about 0.5 wt % to about 10 wt % or about 1 wt % to about 10 wt % based on a total weight of the composition.

The composition for removing edge beads from metal-containing resists according to the present disclosure may be effective (e.g., particularly effective) in removing metal-containing resists, for example, undesirable metal residues, such as tin-based metal residues.

In addition, the developer composition of metal-containing resists according to the present disclosure minimizes or reduces defects present in the metal-containing photoresist layer after the exposure process and allows for easy development, thereby realizing excellent or suitable pattern characteristics.

In addition, excellent or suitable sensitivity and reduced line edge roughness (LER) can be achieved.

In some embodiments, one or more other additives (to be described in more detail later) may be included, and the organic solvent may be included in a balance amount excluding the other included components.

The one or more other additives may be selected from among a surfactant, a dispersant, a moisture absorbent, and a coupling agent.

According to some example embodiments, a method of forming patterns includes the (e.g., act or task) step of removing the edge beads using the aforementioned composition for removing edge beads from the metal-containing resist. For example, the manufactured pattern may be a photoresist pattern. For example, the manufactured pattern may be a negative-type or kind photoresist pattern.

A method of forming patterns according to one or more embodiments includes coating a metal-containing resist composition on a substrate, coating the aforementioned composition for removing edge beads from metal-containing resists along an edge of the substrate, drying and heating to form a metal-containing photoresist layer on the substrate, exposing the metal-containing photoresist layer, and developing the metal-containing photoresist layer.

For example, the forming of patterns using the metal-containing resist composition may include coating a metal-containing resist composition on a substrate (on which a thin film is formed) by spin coating, slit coating, inkjet printing, and/or the like, and drying the coated metal-containing resist composition to form a photoresist layer. The metal-containing resist composition may include a tin-based compound, and for example, the tin-based compound may include at least one of an organic oxy group-containing tin compound or an organic carbonyloxy group-containing tin compound.

For example, the metal-containing resist composition may include a metal compound represented by Chemical Formula 2.

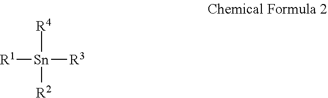

In Chemical Formula 2,

R¹ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C6 to C30 arylalkyl group,
R² to R⁴ may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, an alkoxy or aryloxy group (—OR^{a}, wherein R^{a} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), a carboxyl group (—O(CO)R^{b}, wherein R^{b} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylamido or dialkylamido group (—NR^{c}R^{d}, wherein R^{c} and R^{d} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidato group (—NR^{e}(COR^{f}), wherein R^{e} and R^{f} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidinato group (—NR^{g}C(NR^{h})Rⁱ, wherein R^{g}, R^{h}, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylthio or arylthiol group (—SR^{j}, wherein R^{j} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), or a thiocarboxyl group (—S(CO)R^{k}, wherein R^{k} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), and

at least one selected from among R² to R⁴ is: selected from among an alkoxy group and an aryloxy group (—OR^{a}, wherein R^{a} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof); a carboxyl group (—O(CO)R^{b}, wherein R^{b} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof); an alkylamido group and an dialkylamido group (—NR^{c}R^{d}, wherein R^{c} and R^{d} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof); an amidato group (—NR^{e}(COR^{f}), wherein R^{e} and R^{f} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof); an amidinato group (—NR^{g}C(NR^{h})Rⁱ, wherein R^{g}, R^{h}, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof); an alkylthio group and an arylthiol group (—SR^{j}, wherein R^{j} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof); and/or a thiocarboxyl group (—S(CO)R^{k}, wherein R^{k} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof). That is, at least one selected from among R² to R⁴ is selected from among the alkoxy or aryloxy group represented by —OR^{a}, the carboxyl group represented by —O(CO)R^{b}, the alkylamido or dialkylamido group represented by —NR^{c}R^{d}, the amidato group represented by —NR^{e}(COR^{f}), the amidinato group represented by —NR^{g}C(NR^{h})Rⁱ, the alkylthio or arylthiol group represented by —SRI, and the thiocarboxyl group represented by —S(CO)R^{k}.

The metal compound included in the metal-containing resist composition may be represented by Chemical Formula 3 or Chemical Formula 4.

R⁶_{z}SnO_{(2-(z/2)-(x/2))}(OH)ₓ Chemical Formula 3

In Chemical Formula 3,

R⁶ may be a C1 to C31 hydrocarbyl group, 0<z≤2, and 0<(z+x)≤4;

R⁷ₙSnₘXₗYₖ Chemical Formula 4

wherein, in Chemical Formula 4,
R⁷ may be a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, and/or a (e.g., any suitable) combination thereof,
X may be sulfur (S), selenium (Se), or tellurium (Te),
Y may be —OR^{m} or —OC(═O)Rⁿ,
wherein R^{m} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof,
Rⁿ may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof, and
n, m, l, and k may each independently be an integer of 1 to 20.

In one or more embodiments, the composition for removing edge beads from the metal-containing resists along the edge of the substrate may be coated while rotating the substrate at an appropriate or suitable speed (e.g., 500 rpm or more) (e.g., to form a photoresist layer).

Subsequently, a first heat treatment process of heating the substrate on which the photoresist layer is formed is performed. The first heat treatment process may be performed at a temperature of about 80° C. to about 120° C. and in this process, the solvent is evaporated and the photoresist layer may be more firmly adhered to the substrate.

Then, the photoresist layer is selectively exposed.

For example, examples of light that may be used in the exposure process may include not only light having a short wavelength such as i-line (wavelength 365 nm), KrF excimer laser (wavelength 248 nm), or ArF excimer laser (wavelength 193 nm), but also light having a high energy wavelength such as Extreme UltraViolet (EUV), wavelength 13.5 nm), electron beam (E-Beam), and/or the like.

In some embodiments, the light for exposure may be short-wavelength light having a wavelength range of about 5 nm to about 150 nm, and light having a high energy wavelength such as EUV (Extreme UltraViolet, wavelength 13.5 nm), E-Beam (electron beam), and/or the like.

In the (e.g., act or task) step of forming the photoresist pattern, a negative-type or kind pattern may be formed.

The exposed region of the photoresist layer has a solubility different from that of the unexposed region of the photoresist layer as a polymer is formed by a crosslinking reaction such as condensation between organometallic compounds.

Then, a second heat treatment process is performed on the substrate. The second heat treatment process may be performed at a temperature of about 90° C. to about 200° C. By performing the second heat treatment process, the exposed region of the photoresist layer becomes difficult to be dissolved in a developer.

For example, the photoresist pattern corresponding to the negative tone image may be completed by dissolving and removing the photoresist layer corresponding to the unexposed region using an organic solvent such as 2-heptanone.

Examples of the organic solvent included in the developer composition used in the method of forming patterns according to one or more embodiments may be, for example, one or more of ketones such as methyl ethyl ketone, acetone, cyclohexanone, and/or 2-haptanone, alcohols such as 4-methyl-2-propanol, 1-butanol, isopropanol, 1-propanol, and/or methanol, esters such as propylene glycol monomethyl ether acetate, ethyl acetate, ethyl lactate, n-butyl acetate, butyrolactone, aromatic compounds such as benzene, xylene, and/or toluene, and/or a (e.g., any suitable) combination thereof.

The photoresist pattern, (formed by exposure to not only light having a short wavelength such as i-line (wavelength 365 nm), KrF excimer laser (wavelength 248 nm), or ArF excimer laser (wavelength 193 nm), but also light having high energy such as EUV (Extreme UltraViolet, wavelength 13.5 nm), and/or even also E-beam (electron beam)), may have a width of about 5 nm to about 100 nm. For example, the photoresist pattern may be formed to have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

Also, the photoresist pattern may have a pitch having a half-pitch of less than or equal to about 50 nm, for example, less than or equal to 40 nm, less than or equal to 30 nm, less than or equal to 20 nm, or less than or equal to 15 nm and a line width roughness of less than or equal to about 10 nm, for example, less than or equal to about 5 nm, less than or equal to about 3 nm, or less than or equal to about 2 nm.

A method of forming patterns according to one or more embodiments includes coating a metal-containing resist composition on a substrate, removing edge beads of the metal-containing resists, drying and heating to form a metal-containing photoresist layer on the substrate, exposing the metal-containing photoresist layer, and developing using the aforementioned developer composition of metal-containing resists.

The coating of the metal-containing resist composition on a substrate is the same as described above.

The removing of edge beads of the metal-containing resists may be performed by coating an appropriate or suitable amount of a suitable (e.g., generally known) organic solvent or composition for removing edge beads along the edge of the substrate while spinning the substrate at an appropriate or suitable speed (e.g., 500 rpm or more).

The drying and heating to form a metal-containing photoresist layer on the substrate is the same as described above.

The exposing of the metal-containing photoresist layer is the same as described above.

The photoresist pattern corresponding to the negative tone image may be completed by dissolving the photoresist layer corresponding to the unexposed region using the aforementioned developer composition of metal-containing resists and then removing the photoresist layer.

The metal compound included in the metal-containing resist composition may include at least one of an organic oxy group-containing tin compound or an organic carbonyloxy group-containing tin compound.

Specific non-limiting examples of the metal compound included in the metal-containing resist composition are as described above.

Hereinafter, a method of forming patterns by development is described in more detail with reference to the drawings.

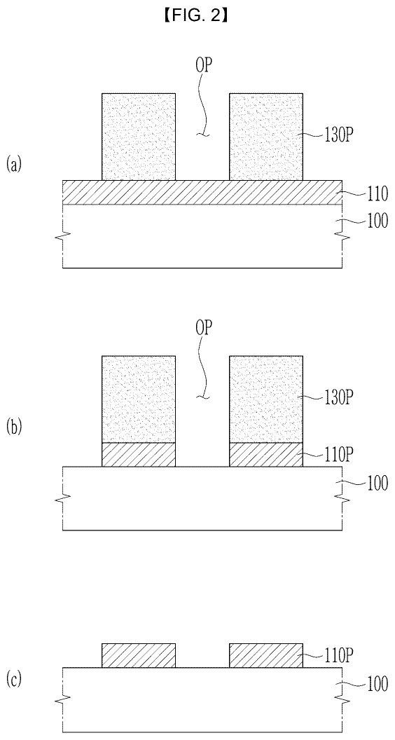

FIG. 2 is cross-sectional views illustrating a process sequence in order to explain a method of forming patterns.

Referring to FIG. 2 (a), the exposed photoresist layer (e.g., coated on the substrate 100) is developed to form a photoresist pattern 130P.

In one or more embodiments, the exposed photoresist layer may be developed to remove an unexposed region of the photoresist layer, and the photoresist pattern 130P including the exposed region of the photoresist layer may be formed.

The photoresist pattern 130P may include a plurality of openings OP.

In one or more embodiments, the development of the photoresist layer may be performed through a negative-tone development (NTD) process. Herein, the developer composition of metal-containing resists according to one or more embodiments may be used as a developer composition.

Referring to FIG. 2 (b), the photoresist pattern 130P is used to process a feature layer (e.g., target layer) 110 from the result shown in FIG. 2 (a).

For example, the feature layer 110 is processed through one or more suitable processes of etching the feature layer 110 exposed through the openings OP of the photoresist pattern 130P, injecting impurity ions into the feature layer 110, forming an additional film on the feature layer 110 through the openings OP, deforming (e.g., removing) a portion of the feature layer 110 through the openings OP, and/or the like. FIG. 2 (b) illustrates an example process of processing a feature pattern 110P by etching the feature layer 110 exposed through the openings OP.

Referring to FIG. 2 (c), the photoresist pattern 130P remaining on the feature pattern 110P in the result shown in FIG. 2 (b) is removed. In order to remove the photoresist pattern 130P, an ashing and stripping process may be used.

A method of forming patterns according to one or more embodiments includes coating a metal-containing resist composition on a substrate, coating the aforementioned composition for removing edge beads from metal-containing resists along an edge of the substrate, drying and heating to form a metal-containing photoresist layer on the substrate, exposing the metal-containing photoresist layer, and developing the metal-containing photoresist layer using the aforementioned developer composition of metal-containing resists.

Each (e.g., act or task) step of the method is substantially the same as described above, but in the removing (e.g., act or task) step of edge beads and the developing (e.g., act or task) step, the composition for removing edge beads from metal-containing resists or the developer composition of metal-containing resists according to embodiments of the present disclosure are concurrently (e.g., simultaneously) used to effectively improve an effect of removing the edge beads and solubility of the unexposed region and thus satisfying needs or desires for processing and patterning of smaller features, resultantly realizing excellent or suitable contrast characteristics, excellent or suitable sensitivity, and reduced line edge roughness (LER).

Hereinafter, the present disclosure will be described in more detail through examples relating to the preparation of the aforementioned composition for removing edge beads from metal-containing resists and developer composition of metal-containing resists. However, the technical features of the present disclosure are not limited by the following examples.

Preparation of Composition for Removing Edge Beads from Metal-containing Resists/Developer Composition

### Example 1 and Example 2

1-Adamantane carboxylic acid or bicyclo[2.2.1]heptane-2-carboxylic acid was mixed with propylene glycol methyl ether acetate (PGMEA) as a solvent according to the composition shown in Table 1, and then, completely dissolved therein by shaking at room temperature (25° C.). Subsequently, the obtained solution was filtered with a PTFE filter material with a pore size of 0.01 μm to prepare each final composition.

### Comparative Example 1 to Comparative Example 4

Each composition was prepared in substantially the same manner as in Example 1 except that the composition was changed as shown in Table 1.

TABLE 1

Developer composition

| | Carboxylic acid | Solvent |
|---|---|---|
| | (wt %) | (wt %) |
| Example 1 | AdA (2.0) | PGMEA (98.0) |
| Example 2 | BCyHepA (10.0) | PGMEA (90.0) |
| Comparative | — | PGMEA (100) |
| Example 1 | | |
| Comparative | AA (2.0) | PGMEA (98.0) |
| Example 2 | | |
| Comparative | SIA (2.0) | PGMEA (98.0) |
| Example 3 | | |
| Comparative | PthA (2.0) | PGMEA (98.0) |
| Example 4 | | |

*AdA: 1-adamantane carboxylic acid
*BCyHepA: bicyclo[2.2.1]heptane-2-carboxylic acid
*AA: Acetic acid
*SIA: Salicylic acid
*PthA: Phthalic acid

### Preparation of Organometal-containing Photoresist Composition

An organometallic compound having the structural unit of Chemical Formula C was dissolved in 4-methyl-2-pentanol at a concentration of 1 wt %, then filtered through a 0.1 μm PTFE syringe filter to prepare a photoresist composition.

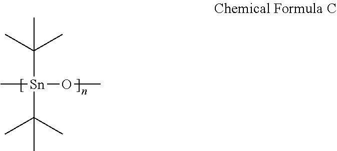

### Evaluation 1: Evaluation of Contrast Performance and Sensitivity

A metal-containing photoresist (PR) composition was spin-coated on an 8-inch wafer at 1,500 rpm for 30 seconds and then, heat-treated at 160° C. for 60 seconds to manufacture a coated wafer.

After exposing this coated wafer to a dose of 10 to 55 mJ in a rectangular shape pattern of 1.2 cm×0.9 cm by using a KrF scanner (PAS 5500/700D, ASML) and heat-treating it at 160° C. for 90 seconds (e.g., to form a metal-containing photoresist layer), the developer compositions according to Example 1, Example 2 and Comparative Examples 1 to 4 were respectively applied thereto to develop the metal-containing photoresist layer and then, finally heat-treated at 240° C. for 60 seconds to obtain patterned wafers. Contrast performance (γ (contrast)) and sensitivity D₁₀₀) were calculated from the contrast curve obtained by measuring the thickness of each exposed area on the patterned wafer, and the results are shown in Table 2. The base of log (D₁₀₀/D₀) is 10.

$$γ ( contrast ) = 1 / log ( {D}_{100} / {D}_{0} )$$

D₁₀₀=Exposure dose at which 100% PR still remains
D₀=Exposure dose at which PR is completely removed

### Evaluation 2: Measurement of CD

The developer is evaluated by injecting it in the development process during the coating-exposure-development process for manufacturing patterned wafers. After completing the process, a line/space CD pattern is formed on the patterned wafer, which is then transferred to Hitachi's GC-5000 CD-SEM measurement equipment to measure the Critical Dimension (CD) size of the area where the half-pitch of the mask pattern is 14 nm. The minimum value of space CD, which is the space between lines, is shown in Table 2.

TABLE 2

| | | | Minimum Space |
|---|---|---|---|
| | γ | Sensitivity | CD |
| | (contrast) | (D₀) | (@14 nm) |
| Example 1 | 27.5 | 23 | 180 |
| Example 2 | 26.3 | 20 | 180 |
| Comparative | 8 | 24 | 350 |
| Example 1 | | | |
| Comparative | 9.6 | 29 | 250 |
| Example 2 | | | |
| Comparative | 10.4 | 21 | 180 |
| Example 3 | | | |
| Comparative | 15.6 | 25 | 180 |
| Example 4 | | | |

Referring to Table 2, when applying the developer composition of metal-containing resists according to Examples, excellent or suitable contrast performance and excellent or suitable sensitivity characteristics are shown, excellent or suitable resolution is obtained, and the occurrence of scum or bridges are minimized or reduced compared to when applying the developer composition of metal-containing resists according to the Comparative Examples.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof. As used herein, the term “combination thereof” refers to a mixture, a laminate, a composite, a copolymer, an alloy, a blend, a reaction product, and/or the like of the constituents.

As used herein, the terms “use,” “using,” and “used” may be considered synonymous with the terms “utilize,” “utilizing,” and “utilized,” respectively. As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The use of “may” when describing embodiments of the inventive concept refers to “one or more embodiments of the inventive concept.”

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinbefore, the certain embodiments of the present disclosure have been described and illustrated, however, it is apparent to a person with ordinary skill in the art that the present disclosure is not limited to one or more embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure, and equivalents thereof.

Reference Numerals

| | |
|---|---|
| 1: substrate support portion | 2: spray nozzle |
| 10: photoresist solution | 12: edge bead |
| 100: substrate | OP: opening |
| 110: feature layer | |
| 110P: feature pattern | 130P: photoresist pattern |

What is claimed is:

1. A solvent-based composition comprising:
a polycyclic aliphatic hydrocarbon compound substituted with at least one carboxyl group; and
an organic solvent,
wherein the solvent-based composition is a composition for removing edge beads from metal-containing resists or a developer composition of metal-containing resists.

2. The solvent-based composition as claimed in claim 1, wherein
the polycyclic aliphatic hydrocarbon compound substituted with at least one carboxyl group is represented by Chemical Formula 1: 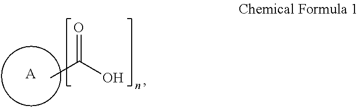
wherein, in Chemical Formula 1,
A is a substituted or unsubstituted C5 to C50 polycyclic aliphatic hydrocarbon group in which at least two rings are fused, and
n is an integer of 1 or greater.

3. The solvent-based composition as claimed in claim 2, wherein
A is a substituted or unsubstituted adamantyl group, a substituted or unsubstituted norbornyl group, a substituted or unsubstituted isobornyl group, a substituted or unsubstituted tricyclodecanyl group, a substituted or unsubstituted tetracyclododecanyl group, a substituted or unsubstituted bicyclo[2.2.1]heptyl group, or a combination thereof.

4. The solvent-based composition as claimed in claim 1, wherein
the polycyclic aliphatic hydrocarbon compound substituted with at least one carboxyl group is any one selected from among compounds in Group 1:

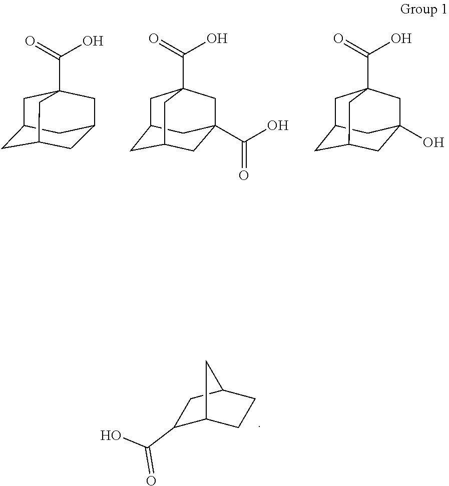

5. The solvent-based composition as claimed in claim 1, wherein
the polycyclic aliphatic hydrocarbon compound substituted with at least one carboxyl group is about 0.1 wt % to about 10 wt % in amount based on a total weight of the solvent-based composition.

6. A method of forming patterns, the method comprising:
coating a metal-containing photoresist composition on a substrate;
coating an edge bead removing composition for removing edge beads from metal-containing resists along an edge of the substrate to remove an edge bead;
drying and heating to form a metal-containing photoresist layer on the substrate;
exposing the metal-containing photoresist layer; and
developing the metal-containing photoresist layer utilizing a developer composition for metal-containing resists,
wherein at least one of the edge bead removing composition or the developer composition is the solvent-based composition as claimed in claim 1.

7. The method as claimed in claim 6, wherein
the metal-containing photoresist composition comprises a metal compound, the metal compound being at least one of an organic oxy group-containing tin compound or an organic carbonyloxy group-containing tin compound.

8. The method as claimed in claim 6, wherein
the metal-containing photoresist composition comprises a metal compound, the metal compound being represented by Chemical Formula 2: 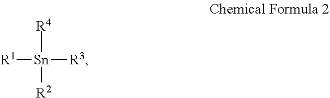
wherein, in Chemical Formula 2,
R² is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C6 to C30 arylalkyl group,
R² to R⁴ are each independently a substituted or unsubstituted C1 to C20 alkyl group; a substituted or unsubstituted C3 to C20 cycloalkyl group; a substituted or unsubstituted C2 to C20 alkenyl group; a substituted or unsubstituted C2 to C20 alkynyl group; a substituted or unsubstituted C6 to C30 aryl group; a substituted or unsubstituted C6 to C30 arylalkyl group; an alkoxy or aryloxy group represented by —OR^{a}, wherein R^{a} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; a carboxyl group represented by —O(CO)R^{b}, wherein R^{b} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an alkylamido or dialkylamido group represented by —NR^{c}R^{d}, wherein R^{c} and R^{d} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an amidato group represented by —NR^{e}(COR^{f}), wherein R^{e} and R^{f} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an amidinato group represented by —NR^{g}C(NR^{h})Rⁱ, wherein R^{g}, R^{h}, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an alkylthio or arylthiol group represented by —SR^{j}, wherein R^{j} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; or a thiocarboxyl group represented by —S(CO)R^{k}, wherein R^{k} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; and
at least one selected from among R² to R⁴ is selected from among the alkoxy or aryloxy group represented by —OR^{a}, the carboxyl group represented by —O(CO)R^{b}, the alkylamido or dialkylamido group represented by —NR^{c}R^{d}, the amidato group represented by —NR^{e}(COR^{f}), the amidinato group represented by —NR^{g}C(NR^{h})Rⁱ, the alkylthio or arylthiol group represented by —SR^{j}, and the thiocarboxyl group represented by —S(CO)R^{k}.

9. The method as claimed in claim 6, wherein
the metal-containing photoresist composition comprises a metal compound represented by Chemical Formula 3 or Chemical Formula 4:
R⁶_{z}SnO_{(2-(z/2)-(x/2))}(OH)ₓ Chemical Formula 3
wherein, in Chemical Formula 3,
R⁶ is a C1 to C31 hydrocarbyl group, 0<z≤2, and 0<(z+x)≤4;
R⁷ₙSnₘXₗYₖ Chemical Formula 4
wherein, in Chemical Formula 4,
R⁷ is a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X is sulfur (S), selenium (Se), or tellurium (Te),
Y is —OR^{m} or —OC(═O)Rⁿ, and
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
n, m, l, and k are each independently an integer of 1 to 20.

10. A composition for removing edge beads from metal-containing resists being the solvent-based composition as claimed in claim 1.

11. A developer composition for metal-containing resists being the solvent-based composition as claimed in claim 1.

12. The method as claimed in claim 6, wherein
the edge bead removing composition is the solvent-based composition.

13. The method as claimed in claim 6, wherein the developer composition is the solvent-based composition.

14. A solvent-based composition comprising:
a polycyclic aliphatic hydrocarbon compound substituted with at least one carboxyl group; and
an organic solvent.

15. A method of forming patterns, the method comprising:
coating a metal-containing photoresist composition on a substrate;
coating an edge bead removing composition for removing edge beads from metal-containing resists along an edge of the substrate to remove an edge bead;
drying and heating to form a metal-containing photoresist layer on the substrate;
exposing the metal-containing photoresist layer; and
developing the metal-containing photoresist layer utilizing a developer composition for metal-containing resists,
wherein at least one of the edge bead removing composition or the developer composition comprises the solvent-based composition as claimed in claim 14.

16. A composition for removing edge beads from metal-containing resists comprising the solvent-based composition as claimed in claim 14.

17. A developer composition for metal-containing resists comprising the solvent-based composition as claimed in claim 14.

18. The method as claimed in claim 15, wherein
the edge bead removing composition comprises the solvent-based composition.

19. The method as claimed in claim 15, wherein
the developer composition comprises the solvent-based composition.

20. The method as claimed in claim 15, wherein
the edge bead removing composition and the developer composition both comprise the solvent-based composition.
